(19) United States
(12) Patent Application Publication
(10) Pub. No.: US 2008/0122542 A1
(43) Pub. Date: May 29, 2008

(54) ENHANCED AMPLIFIER WITH AUXILIARY PATH BIAS MODULATION

(76) Inventors: Gregory Bowles, Nepean (CA); Scott Widdowson, Ottawa (CA)

Correspondence Address: NORTEL NETWORKS LIMITED, 5601 GRANITE PARKWAY, SUITE 750, PLANO, TX, 75024, US

(21) Appl. No.: 11/563,535

(22) Filed: Nov. 27, 2006

(51) Int. Cl. H03F 3/16; H03F 3/68; H03F 3/20

(52) U.S. Cl. 330/277; 330/136; 330/124 R

(57) ABSTRACT

An amplification unit comprising a signal splitter operable to split an input signal into a first signal and a second signal such that the two resulting signal portions are in quadrature, a main driver operable to create a third signal from the first signal, and a main amplifier operable to amplify the first driver signal. Amplification unit also may include an auxiliary driver capable of creating a fourth signal from the second signal, an auxiliary amplifier capable of amplifying the second signal, a bias control component operable to control at least part of the output of the auxiliary amplifier, and a signal combiner operable to combine the third signal and the fourth signal and realigning the phase of the third signal and fourth signal. In some embodiments enhanced amplification unit is a Doherty-type amplifier.

### CROSS-REFERENCE TO RELATED APPLICATIONS

This application is related to U.S. patent application Ser. No. 11/537,084, filed on Sep. 29, 2006 and entitled “Enhanced Doherty Amplifier With Asymmetrical Semiconductors,” which is incorporated herein by reference for all purposes.

### STATEMENT REGARDING FEDERALLY SPONSORED RESEARCH OR DEVELOPMENT

Not applicable.

### REFERENCE TO A MICROFICHE APPENDIX

Not applicable.

### FIELD OF THE INVENTION

The present invention relates generally to signal amplification and, more particularly, to a device and method for increasing the efficiency of an amplification device.

### BACKGROUND OF THE INVENTION

Wireless devices use Radio Frequencies (RF) to transmit information. For example, cell phones use amplified RF to transmit voice data to base stations, which allow signals to be relayed to communications networks. Other existing wireless communication devices include Bluetooth, HomeRF and WLAN. In a conventional wireless device, the power amplifier consumes most of the power of the overall wireless system. For systems that run on batteries, a power amplifier with a low efficiency results in a reduced communication time for a given battery size. For continuous power systems, a decrease in efficiency results in increased power usage and heat removal requirements, which may increase the equipment and operating costs of the overall system.

For this reason, much effort has been expended on increasing the efficiency of RF power amplifiers. One type of amplifier that may increase power amplifier efficiency is a Doherty-type power amplifier. A common Doherty-type power amplifier design includes a main amplifier and an auxiliary amplifier. The main amplifier is operated to maintain optimal efficiency up to a certain power level and allows the auxiliary amplifier to operate above that level. When the power amplifier is operated at a high output power level, the main amplifier will be heavily compressed such that non-linearities are introduced into the amplified signal. In common Doherty-type amplifiers, the main and auxiliary amplifiers are composed of the same type of amplifiers with the same power amplification rating. These Doherty-type amplifiers develop an efficiency peak 6 dB below the full power which will be equal in magnitude to the maximum efficiency of the system. Due to the importance and widespread use of wireless technologies, it would be desirable to have a Doherty-type device capable of an increased efficiency over a wide range of power amplification levels.

### SUMMARY OF THE INVENTION

In one embodiment, an amplification unit is disclosed which comprises a signal splitter operable to split an input signal into a first signal and a second signal such that the two resulting signal portions are in quadrature, a main driver operable to create a third signal from the first signal, and a main amplifier operable to amplify the signal. In this embodiment, the amplification unit also discloses an auxiliary driver capable of creating a fourth signal from the second signal, an auxiliary amplifier capable of amplifying the second signal, a bias control component operable to control at least part of the output of the auxiliary amplifier, and a signal combiner operable to combine the third signal and the fourth signal and realigning the phase of the amplified third signal and amplified fourth signal.

In another embodiment, a method of amplifying an input signal is disclosed which comprises separating the input signal into a first portion and a second portion, amplifying the first portion using a main driver and a main amplifier and the second portion using an auxiliary driver and an auxiliary amplifier, controlling the amplification of the second portion using a bias control, and combining the amplified first portion and the amplified second portion.

In yet another embodiment, an enhanced amplification unit is disclosed which comprises a signal splitter having an input, a first output, and a second output, wherein the signal splitter is operable to receive an input and to split the input into a first signal and a second signal, wherein the first signal is passed to a first signal splitter signal output and the second signal is passed to a second signal splitter signal output and wherein the first signal and second signal are in quadrature. This unit also comprises a main driver having a main driver signal input and a main driver signal output, wherein the main driver receives the first signal from the signal splitter first output, produces a third signal from the first signal, and transmits the third signal through the main driver signal output. This unit further comprises a main amplifier having a main amplifier input and a main amplifier output, wherein the main amplifier receives the third signal from the main driver, produces an amplified third signal, and transmits the amplified third signal through the main amplifier signal output. In addition, this unit also comprises an auxiliary driver having an auxiliary driver signal input and an auxiliary driver signal output, wherein the auxiliary driver receives the second signal from the signal splitter second output, produces a fourth signal from the second signal, and transmits the fourth signal through the auxiliary driver signal output. This unit also comprises an auxiliary amplifier having an auxiliary amplifier input and an auxiliary amplifier output, wherein the auxiliary amplifier receives the forth signal from the auxiliary driver, produces an amplified forth signal, and transmits the amplified fourth signal through the auxiliary amplifier signal output, a bias control component coupled to the auxiliary amplifier, wherein the bias control component is operable to control at least part of the amplified fourth signal created by the auxiliary amplifier, and a signal combiner, wherein the signal combiner is operable to combine the amplified third signal and the amplified fourth signal and realign the phase of the amplified third signal and amplified fourth signal.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

FIG. 1 is a block diagram of an enhanced amplification unit.

FIG. 2 is an expanded block diagram of an embodiment of an enhanced amplification unit.

FIG. 3 is a graphical representation of an enhanced amplification unit efficiency curve.

FIG. 4 is a flow chart of a method for selecting semiconductor devices for an enhanced amplification unit.

FIG. 5 is a graphical representation of several efficiency curves.

FIG. 6 is a block diagram of an alternative embodiment of an enhanced amplification unit with output signal feedback and a pre-distortion linearizer.

FIG. 7 is a block diagram of an alternative embodiment of an enhanced amplification unit with main path, auxiliary path and a bias control component connected to the auxiliary driver.

FIG. 8 is a graph of efficiency versus output power with and without auxiliary driver bias modulation.

FIG. 9 is a graph of phase versus output power with and without auxiliary driver bias modulation.

FIG. 10 is a graph of gain versus output power with and without auxiliary driver bias modulation.

FIG. 11 is a block diagram of an alternative embodiment of an enhanced amplification unit with main path, auxiliary path and a bias control component connected to the auxiliary amplifier.

FIG. 12 is a graph of efficiency versus output power with and without auxiliary amplifier bias modulation.

FIG. 13 is a graph of phase versus output power with and without auxiliary amplifier bias modulation.

FIG. 14 is a graph of gain versus output power with and without auxiliary amplifier bias modulation.

FIG. 15 is a block diagram of an alternative embodiment of an enhanced amplification unit with main path, auxiliary path and two bias control components.

FIG. 16 is a block diagram of an alternative embodiment of an enhanced amplification unit with main path, auxiliary path, pre-distortion linearizer and two bias control components.

FIG. 17A is a graphical representation of an input signal.

FIG. 17B is a graphical representation of a main portion of a pre-shaped input signal.

FIG. 17C is a graphical representation of an auxiliary portion of a pre-shaped input signal.

FIG. 18 is a block diagram of a base station.

### DETAILED DESCRIPTION OF THE PREFERRED EMBODIMENTS

It should be understood at the outset that although an exemplary implementation of one embodiment of the present disclosure is illustrated below, the present system may be implemented using any number of techniques, whether currently known or in existence. The present disclosure should in no way be limited to the exemplary implementations, drawings, and techniques illustrated below, including the exemplary design and implementation illustrated and described herein, but may be modified within the scope of the appended claims along with their full scope of equivalents. It is further understood that as used herein, terms such as coupled, connected, electrically connected, in signal communication, and the like may include direct connections between components, indirect connections between components, or both, as would be apparent in the overall context of a particular embodiment. The term coupled is intended to include, but not be limited to, a direct electrical connection. The terms transmit, transmitted, or transmitting are intended to include, but not be limited to, the electrical transmission of a signal from one device to another.

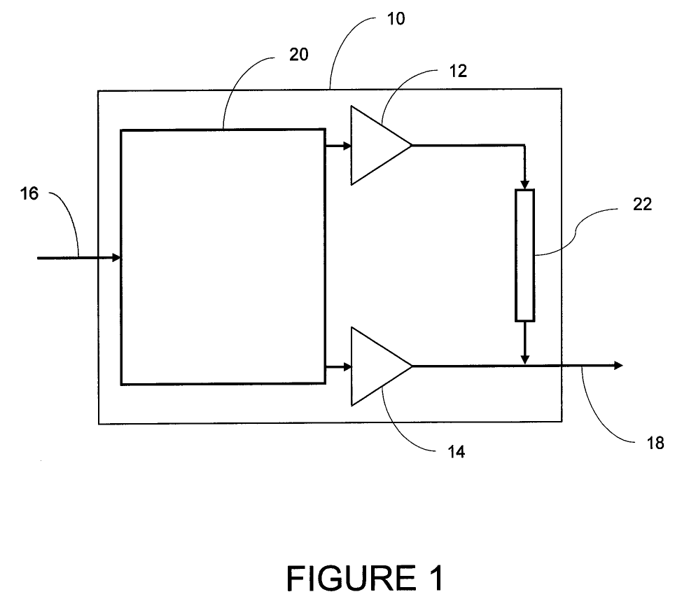

As shown in FIG. 1, the present disclosure contemplates an enhanced amplification unit 10. In some embodiments enhanced amplification unit 10 is a Doherty-type amplifier. The enhanced amplification unit 10 comprises an input signal line 16, a main amplifier 12, an auxiliary amplifier 14, a signal preparation unit 20, a main amplifier impedance transformer 22, and an output signal line 18. An input signal is passed into input signal line 16 and into signal preparation unit 20. Signal preparation unit 20 transmits the input signal from input signal line 16 into main amplifier 12, and signal preparation unit 20 phase shifts the input signal from input signal line 16 and transmits the phase shifted signal to auxiliary amplifier 14. Main amplifier impedance transformer 22 receives output from main amplifier 12. Output from auxiliary amplifier 14 and the main amplifier impedance transformer 22 are combined to form an output signal that is transmitted to signal output line 18. This amplifier may be augmented through the use of bias control components which can be used in conjunction with main amplifier 12, auxiliary amplifier 14, or other components.

Signal preparation unit 20 is capable of splitting, dividing, or otherwise providing to main amplifier 12 and auxiliary amplifier 14 a signal either directly from input signal line 16, or a signal that has been modified by another component, structure, or device using input signal line 16 as a source. Signal preparation unit 20 may be embodied as any device capable of passing at least part of a signal from input signal line 16 to main amplifier 12 and auxiliary amplifier 14. Signal preparation unit 20 may pass the same signal to both main amplifier 12 and auxiliary amplifier 14, or may pass a modified signal to main amplifier 12, auxiliary amplifier 14, or both main amplifier 12 and auxiliary amplifier 14. Signal preparation unit 20 is further capable, in some embodiments, of introducing a phase change into the signal from input signal line 16 which is passed to main amplifier 12, auxiliary amplifier 14, or both main amplifier 12 and auxiliary amplifier 14. Signal preparation unit 20 is illustrated as an electronic device; however, it is expressly understood that in some embodiments signal preparation unit 20 may be replaced with a direct electrical connection between input signal line 16, main amplifier 12, and auxiliary amplifier 14.

It is expressly understood that the phase shift introduced by signal preparation unit 20 will be applied to at least one of the signals created by signal preparation unit 20. This process of introducing a phase shift into the enhanced amplification unit 10, amplifying the signal from input signal line 16, then aligning the signal may be accomplished in any way known to one skilled in the art. In some embodiments, signal preparation unit 20 transmits a phase shifted signal into auxiliary amplifier 14 and a non-phase shifted signal into main amplifier 12. In other embodiments, signal preparation unit 20 transmits a phase shifted signal into main amplifier 12 and a non-phase shifted signal into auxiliary amplifier 14. In yet other embodiments, signal preparation unit 20 transmits a phase shifted signal into both main amplifier 12 and auxiliary amplifier 14. In each of these embodiments, a second phase shift is introduced by main amplifier impedance transformer 22, so that the signal leaving main amplifier impedance transformer 22 is in phase with the signal leaving auxiliary amplifier 14. It is further understood that, in some embodiments, when signals meet at signal output line 18, the signals may be in phase. It is understood that while an impedance transformer is used in this embodiment, any device capable of introducing an offset, including a phase offset (e.g. a 90 degree offset) or a time offset, could be used.

In an embodiment, main amplifier 12 and auxiliary amplifier 14 comprise different semiconductor amplification devices. In order to enhance the efficiency of enhanced amplification unit 10, main amplifier 12 and auxiliary amplifier 14 may be semiconductor devices of different material compositions, different designs, or both different material compositions and different designs. The use of a first semiconductor device for main amplifier 12 and a second semiconductor device for the auxiliary amplifier 14, wherein the first semiconductor device is not the same as the second semiconductor device, can be used to enhance the efficiency of enhanced amplification unit 10. Main amplifier 12 and auxiliary amplifier 14 may each independently comprise any semiconductor technology or family capable of being used as an amplifier, including, but not limited to, lateral double-diffused metal oxide semiconductor (LDMOS), complementary metal oxide semiconductor (CMOS), metal oxide semiconductor field effect transistor (MOSFET), metal semiconductor field effect transistor (MESFET), heterojunction bipolar transistor (HBT), heterojunction field effect transistor (HFET), high electron mobility transistor (HEMT) and bipolar junction transistor (BJT). Material compositions of main amplifier 12 and auxiliary amplifier 14 may include, but are not limited to, silicon (Si), indium phosphide (InP), gallium arsenide (GaAs), and gallium nitride (GaN). In one embodiment, main amplifier 12 and auxiliary amplifier 14 are a set of mixed semiconductor devices whereby the material composition, semiconductor family, or both the material composition and semiconductor family of main amplifier 12 and auxiliary amplifier 14 are not the same (i.e., are different). Use of a main amplifier 12 having a different amplifier design from auxiliary amplifier 14 may enhance the operational efficiency of the amplification unit. For the sake of clarity, the phrase “amplifier design” shall refer to the semiconductor family and/or material composition of a particular amplifier. In addition, the power ratings of main amplifier 12 and auxiliary amplifier 14 may be different in order to change the location of the maximum efficiency in back-off of the enhanced amplification unit 10.

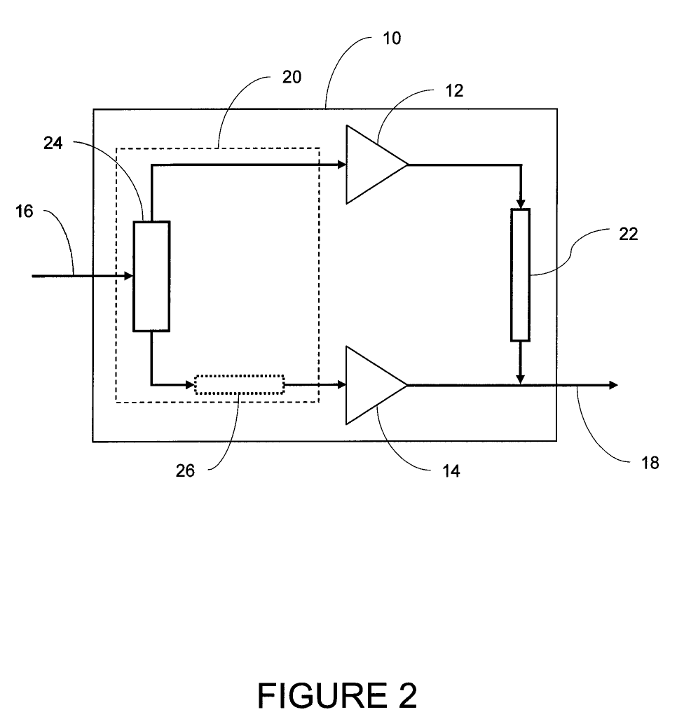

FIG. 2 illustrates another embodiment of enhanced amplification unit 10. In this embodiment, enhanced amplification unit 10 contains a modified version of signal preparation unit 20. This modified version of signal preparation unit 20 contains a signal splitter 24 and an auxiliary path phase offset 26. In this embodiment, an input signal is introduced through input signal line 16, and transmitted into signal splitter 24. Signal splitter 24 splits the input signal, without modifying the input signal, into two substantially similar signals. One of the two signals leaving signal splitter 24 is passed into main amplifier 12 and the other signal leaving signal splitter 24 is passed into auxiliary path phase offset 26. Auxiliary path phase offset 26 introduces a phase shift to the signal from signal splitter 24, in some embodiments, wherein that phase shift may be 90 degrees, and transmits this phase shifted signal into auxiliary amplifier 14. Main amplifier 12 receives a signal from signal splitter 24, amplifies this signal, and transmits this main amplifier amplified signal into main amplifier impedance transformer 22. Main amplifier impedance transformer 22 introduces a phase shift to the main amplifier amplified signal, which in some embodiments is a phase shift of substantially similar qualities as the phase shift introduced by auxiliary path phase offset 26.

When signal splitter 24 splits the signal, it transmits the signal along a main path and an auxiliary path. The main path is the path in which main amplifier 12 is present which runs in between signal splitter 24 and output signal line 18. The auxiliary path is the path in which auxiliary amplifier 14 is present which runs in between signal splitter 24 and output signal line 18.

The output signal is transmitted through output signal line 18 and formed by main amplifier impedance transformer 22 and auxiliary amplifier 14. Quarter wavelength impedance transformers may be used as main amplifier impedance transformer 22, auxiliary path phase offset 26, and within signal preparation unit 20, and may function as phase shifters that may introduce phase change and impedance inversion. One of the innovative features is that by phase shifting both the output from main amplifier 12 and the input to auxiliary amplifier 14, the amplifiers may be driven in phase quadrature. The phrase phase quadrature is intended to refer to the state where two signals are out of phase by 90 degrees.

It is expressly understood that, in some embodiments, enhanced amplification unit 10 may be operated in a state that is shifted away from quadrature so as to ensure that the amplified signals combined in output signal line 18 are in phase to account for variations introduced by combining mixed semiconductor device technologies or materials or power ratings or bias conditions or any combination thereof.

It is expressly understood that transistors are devices which control the flow of current between two points and may be divided into general categories, which include, but are not limited to, bipolar junction transistors (BJTs) and field effect transistors (FETs). Some of these devices have three or more terminals, which substantially correspond with the input, output and common terminals of the device. In the exemplary example of the BJT these include terminals which may be named: base, collector and emitter. In the exemplary example of the FET these include terminals which may be named: gate, drain, and source. It is understood that other terminals are known to one skilled in the art, such as the body terminal. It is expressly understood that any references to the terms “base” or “gate” are not intended to be limiting, should not reference a specific type of transistor, and are used for exemplary purposed only. Any type of transistor, including any type of transistor capable of controlling current or voltage, may be used with the embodiments disclosed herein.

In the embodiment shown in FIG. 2, main amplifier 12 is biased in Class AB, and auxiliary amplifier 14 is biased in Class C. Class A amplifiers conduct current at all times, Class B amplifiers are designed to amplify half an input wave signal, and Class AB is intended to refer to the Class of amplifier which combines the Class A and Class B amplifier. As a result of the Class B properties, Class AB amplifiers are operated in a non-linear region that is only linear over half the wave form. Class C amplifiers are biased well beyond cutoff, so that current, and consequently the input signal, is amplified less than one half the duration of any given period. The Class C design provides higher power-efficiency than Class B operation but with the penalty of higher input-to-output nonlinearity. One of the innovative features of the present disclosure teaches how to optimize the selection of different amplifier designs for main amplifier 12 and auxiliary amplifier 14 and use the properties of each amplifier class to design an efficient enhanced amplification unit 10.

In some embodiments, the term bias is intended to refer to the process by which a signal is applied by, in some embodiments, by a bias control module to control or develop an operating condition. The phrase ‘operating condition’ is intended to include, but not be limited to the condition of the device in the cutoff, active, or saturation condition. This example is given for exemplary purposes only as other conditions are expressly understood by one skilled in the art. These conditions may, in some embodiments, define the operational behavior of a transistor. The operating condition may be achieved by applying a voltage to a transistor until a desired operating point is achieved. This operating point may be determined by the voltage itself, or the quiescent current that develops on a terminal of a transistor. The term operating point generally refers to the intersection on a voltage-current graph where the transistor characteristic is intersected by a load line.

A bias control module may be used to manipulate the bias voltage of a transistor. For example, if it is desired that the transistor is to remain ‘off’ state, then the voltage applied by the bias control module will be set so that the operating condition of the transistor is in the cutoff region. In another example, if it is desired to turn the transistor ‘on’ then the voltage will be increased such that the transistor will be operated in the active region. It is understood that the bias control module may be connected to different terminals on the transistor including, but not limited to, the gate terminal and the base terminal.

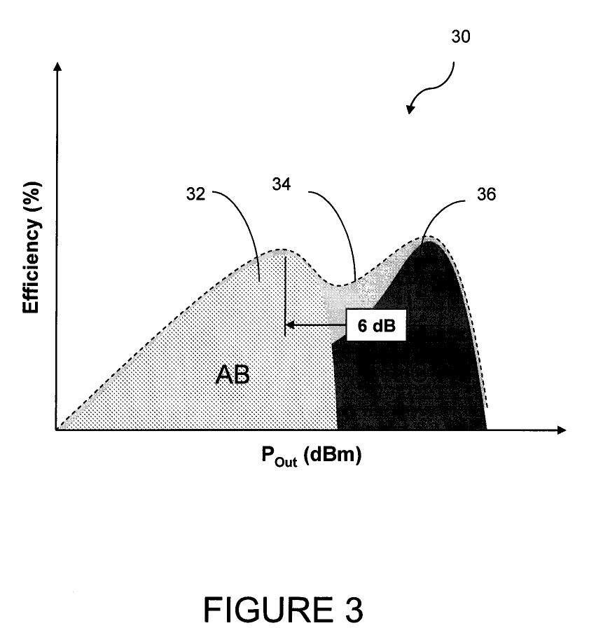

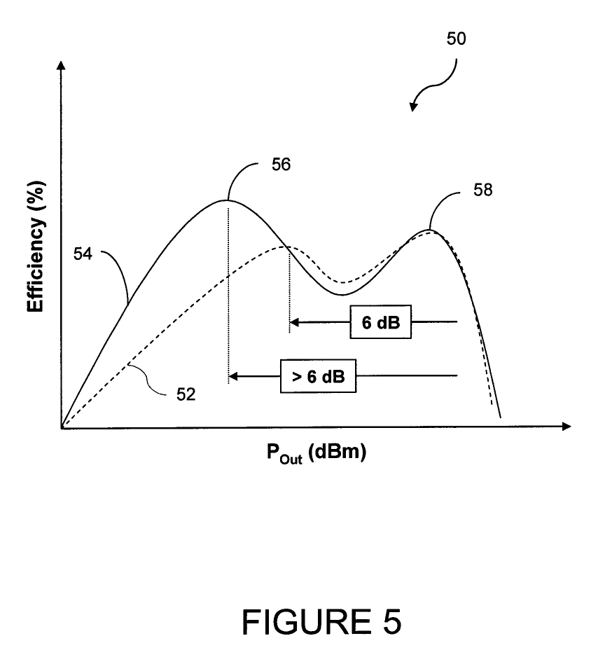

One of the advantages of the disclosed enhanced amplification unit 10 is the increased efficiency created through the use of a first amplifier design for main amplifier 12 and a second amplifier design for auxiliary amplifier 14, wherein the first amplifier design and the second amplifier design are not the same. This efficiency is evident in the enhanced linearity of enhanced amplification unit 10. The efficiency of an amplifier may be measured by reference to the Power Added Efficiency (PAE). The PAE is defined as the difference between the amplifier input signal power and amplifier output signal power divided by the Direct Current (DC) power input to the amplifier. The PAE may be plotted as a function of output power (Pout), Pout is in decibels above 1 mill watt (dBm), as shown in FIGS. 3 and 5.

FIG. 3 is an efficiency graph 30 of enhanced amplification unit 10, wherein main amplifier 12 and auxiliary amplifier 14 have identical, or substantially similar, physical amplifier designs but are biased in Class AB and C, respectively. This figure shows a main amplifier output result 32 (Class AB), an auxiliary amplifier output result 36 (Class C), and the combination of main amplifier output result 32 and auxiliary amplifier output result 36 as a combined output result 34. The use of an amplifier design for main amplifier 12 with high efficiency creates an increase in the height of first efficiency result 32 without substantially affecting the amplifier linearity. Main amplifier 12 operates whenever enhanced amplification unit 10 is amplifying an input signal; an increase in the efficiency of main amplifier 12 improves the efficiency of enhanced amplification unit 10. Moreover, combined output result 34 demonstrates that the independent choice of amplifier designs for main amplifier 12 and auxiliary amplifier 14 allows for the development of enhanced efficiency by design in the back-off of the output, which is desirable in today's modulation systems.

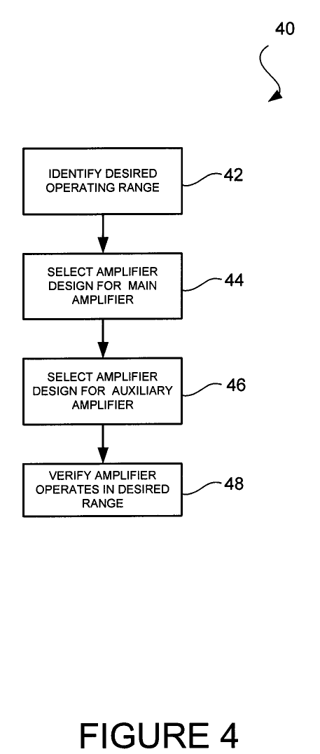

FIG. 4 illustrates a method for determining a first amplifier design 40 of main amplifier 12 and a second, different amplifier design of auxiliary amplifier 14 that may begin with identifying the desired operating range for enhanced amplification unit 10 (Block 42). Operating characteristics that may be used to determine the operating range include, without limitation, the power input level, power output level, operating Peak to Average Ratio (PAR), and frequency operating range. Once the desired operating range has been determined, the amplifier design for main amplifier 12 may be determined (Block 44). In general, main amplifier 12 materials may be selected such that main amplifier 12 will operate in a high efficiency range for the given enhanced amplification unit 10 operating range. In an embodiment, main amplifier 12 may be a GaAs HBT or a GaN HFET. The amplifier design for auxiliary amplifier 14 also may be determined (Block 46). Among other considerations in choosing an auxiliary amplifier 14 design may be a requirement that auxiliary amplifier 14 function as an open circuit with a high impedance when OFF, and have a turn ON point compatible with main amplifier 12 operating range. A CMOS or LDMOS device may exhibit the appropriate OFF characteristics for use as auxiliary amplifier 14. The design choices may then be verified to determine that they operate within the desired ranges (Block 48). Computer simulation or physical testing may be conducted to provide this verification. In various embodiments, main amplifier 12 may be a GaAs HBT, and auxiliary amplifier 14 may be a LDMOS; alternatively, main amplifier 12 may be a GaN HFET and auxiliary amplifier 14 may be a LDMOS; alternatively main amplifier 12 may be a GaAs HBT, and auxiliary amplifier 14 may be a CMOS; alternatively, main amplifier 12 may be a GaN HFET, and auxiliary amplifier 14 may be a CMOS.

FIG. 5 is a graph 50 that shows some of the advantages of one embodiment of the present disclosure using a first output result 54 from enhanced amplification unit 10, wherein, main amplifier 12 is a GaN HFET and auxiliary amplifier 14 is LDMOS. For first output result 54, the power rating of main amplifier 12 is less than the power rating of auxiliary amplifier 14. Graph 50 also shows a second output result 52 from a Doherty amplifier with two identical LDMOS amplifiers. The second output result 52 demonstrates peak efficiency at 6 dB of back-off approaching that of the maximum efficiency in full compression 58, which reflects a design wherein identical devices are used. In contrast, first output result 54 demonstrates peak efficiency at more than 6 dB back-off 56 that exceeds the maximum efficiency in full compression 58, which reflects the use of a smaller more efficient device as main amplifier 12. Furthermore, full power is still maintained through use of a proportionally larger auxiliary amplifier 14 such that combined power rating is equivalent to that for second output result 52. The choice of materials of enhanced amplification unit 10 are provided for illustrative purposes only, as any type and composition of device may be used as both main amplifier 12 and auxiliary amplifier 14. It is envisioned that, in this embodiment, main amplifier 12 and auxiliary amplifier 14 are capable of processing a signal with a frequency ranging from 800 MHz to 3.5 GHz, and can have a combined efficiency of greater than 30%; however, it is expressly contemplated that the disclosed embodiments may be used in any frequency range.

Another advantage illustrated by FIG. 5 is the complexity of enhanced amplification unit 10 output result 54 as compared to the LDMOS amplifier second output result 52. The resulting enhanced amplification unit 10 first output result 54 reflects the components of the contributing amplifier paths. This complex output path allows for the customization of output parameters based upon design choices previously unavailable without the variation in amplifier design. These output parameters include, but are not limited to, the customization of the peak to average signal to virtually any desired level.

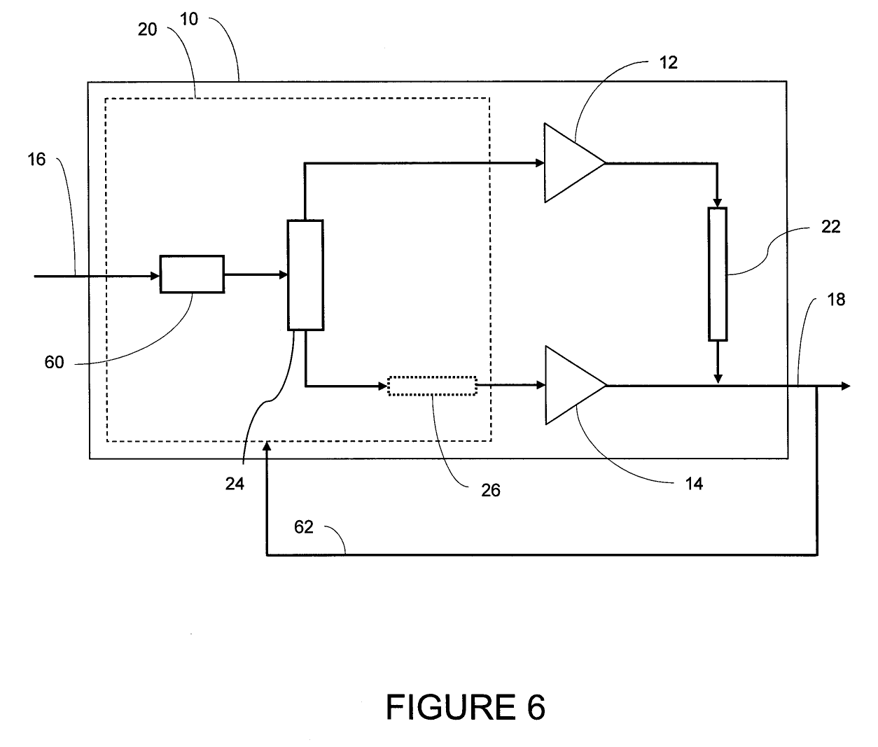

An embodiment of an enhanced amplification unit 10 is shown by FIG. 6. This embodiment of enhanced amplification unit 10 also has a main amplifier 12 and auxiliary amplifier 14 connected in parallel, a main amplifier impedance transformer 22 connected to main amplifier 12 and auxiliary amplifier 14, and an output signal line 18 connected to auxiliary amplifier 14 and main amplifier impedance transformer 22. Again, the amplifier designs of the main and auxiliary amplifiers are dissimilar. In this embodiment, a signal is introduced through an input signal line 16, and transmitted into a pre-distortion linearizer 60 which pre-distorts the signal and transmits the signal into signal splitter 24. Signal splitter 24 splits the signal from pre-distortion linearizer 60 into two substantially similar input signals, and transmits these signals into main amplifier 12 and auxiliary path phase offset 26. The signal from auxiliary path phase offset 26 is transmitted into auxiliary amplifier 14. The output signal from main amplifier 12 is then passed from main amplifier 12 through a main amplifier impedance transformer 22 and becomes a modified output from main amplifier 12. The modified output of main amplifier 12 to main amplifier impedance transformer 22 combines with the output of the signal from auxiliary amplifier 14, becomes the output signal, and exits enhanced amplification unit 10 through output signal line 18. In addition, a feedback signal line 62 is connected from the output signal line 18 to the signal preparation unit 20, which allows pre-distortion linearizer 60 to monitor the signal in output signal line 18.

The output signal which is created from main amplifier impedance transformer 22 and the output from auxiliary amplifier 14 may be in phase. This may be accomplished in any way known to one skilled in the art, including, but not limited to, realigning the phasing using baseband/digital delay techniques, or through length of track radio frequency techniques. Baseband/digital delay techniques are intended to refer to any delay techniques that include, but are not limited to, those that digitally delay the transmission of signals, and radio frequency techniques are intended to refer to any method involving radio frequency signals, including, but not limited to, adjusting the length of the signal track or path. Feedback signal line 62 allows signal preparation unit 20 to monitor the signal leaving enhanced amplification unit 10, and to make adjustments to pre-distortion linearizer 60 or signal splitter 24 or auxiliary path phase offset 26.

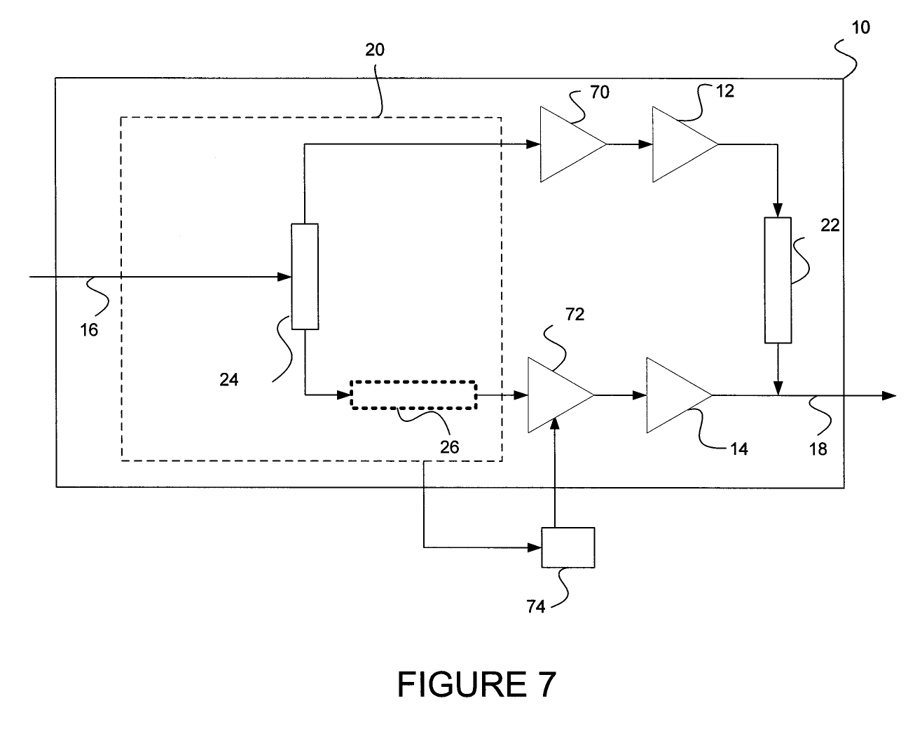

An embodiment of an enhanced amplification unit 10 is shown by FIG. 7. This embodiment of enhanced amplification unit 10 also has a main amplifier 12 and auxiliary amplifier 14 connected in parallel, a main amplifier impedance transformer 22 connected to main amplifier 12 and auxiliary amplifier 14, and an output signal line 18 connected to auxiliary amplifier 14 and main amplifier impedance transformer 22. Main driver 70 has been placed in series in between the main amplifier 12 and signal splitter 24. In addition, auxiliary driver 72 has been placed in series in between auxiliary amplifier 14 and auxiliary path phase offset 26. Main driver 70 and auxiliary driver 72 are used to provide an output to amplification devices they are connected to as known to one skilled in the art. It is understood that, in some embodiments, main driver 70 and auxiliary driver 72 may function as amplification devices operating in as an additional stage in conjunction with amplification devices they are coupled to. In this embodiment, auxiliary driver bias control module 74 is connected to auxiliary driver 72 and signal preparation unit 20. In the embodiment shown in FIG. 7, the amplifier designs of main amplifier 12 and auxiliary amplifier 14 may be dissimilar or consistent, with main amplifier 12 having, in some embodiments, approximately half the peak power rating of auxiliary amplifier 14. In the example shown in FIG. 7, signal splitter 24 may be implemented as an analog power splitter, such as a radio frequency (RF) power splitter, or a digital power splitter. Auxiliary amplifier 14, in some embodiments, may be fundamentally biased in Class C. In one embodiment, the main amplifier 12 may have approximately 100 W peak power capacity and the auxiliary amplifier 14 may have approximately 200 W peak power capacity.

In this embodiment, a signal is introduced through an input signal line 16, and transmitted into signal into signal splitter 24. It is understood that if an RF power splitter is used, the signal for the main path and auxiliary path may be developed from the single input, and that if a digital power splitter is used, a power split may be preformed within the digital input circuitry of the digital power split device in any way known to one skilled in the art. It is further understood that signal splitter 24 splits the signal from signal line 16 into two input signals, and transmits these signals into main driver 70 which transmits a modified signal into main amplifier 12 and auxiliary path phase offset 26. The signal from auxiliary path phase offset 26 is transmitted into auxiliary driver 72 which transmits a modified signal into auxiliary amplifier 14. The output signal from main amplifier 12 is then passed from main amplifier 12 through a main amplifier impedance transformer 22 and becomes a modified output from main amplifier 12. The modified output of main amplifier 12 to main amplifier impedance transformer 22 combines with the output of the signal from auxiliary amplifier 14, becomes the output signal, and exits enhanced amplification unit 10 through output signal line 18.

While signal splitter 24 is illustrated as being within enhanced amplification unit 10, it is expressly understood that in this, or in any embodiment disclosed, signal splitter 24 may be located outside of enhanced amplification unit 10. In embodiments where signal splitter 24 is located outside of enhanced amplification unit 10, input signal line 16 could be replaced with two separate signal input lines, with the main path having a first signal input and the auxiliary path having a second signal input. Therefore, enhanced amplification unit 10 is capable of functioning as a single input device or as a dual input device.

FIG. 7 also illustrates the use of auxiliary driver bias control module 74. Bias control module 74 adjusts the bias voltage applied to auxiliary driver 72. Therefore, auxiliary driver bias control module 74 adjusts the threshold and rate at which the auxiliary driver amplifier gate bias is applied to the auxiliary driver 72 while taking into consideration the input power. The gate bias modulation of auxiliary driver 72 provides further efficiency improvement in back-off and reduces the complexity of the phase response, or more specifically the amplitude modulated—phase modulated (AM-PM) transfer function.

While in FIG. 7 the bias control module is coupled to the auxiliary path, it is expressly understood that the bias control module may also be used to modify the bias of the main path driver and main path amplifier. It is further understood that one or more bias control modules could be coupled to the main path as well as the auxiliary path. This disclosure should not be interpreted to limit the use of the bias control module to modify devices only within the auxiliary path.

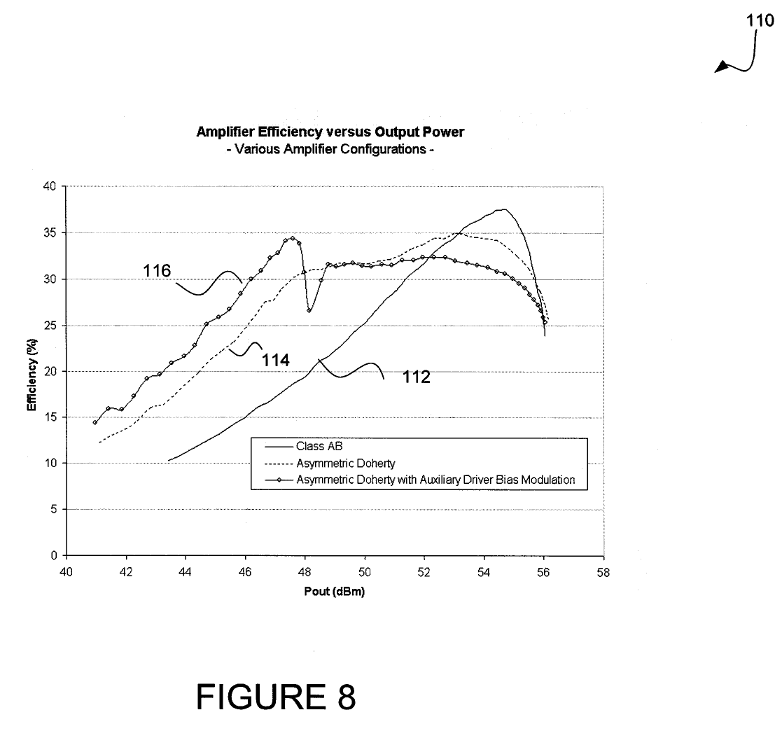

FIG. 8 is a graph 110 showing the amplifier efficiency versus the output power of a balanced AB amplifier 112, a Doherty with similar amplification devices 114, and an enhanced amplification unit 10 with auxiliary driver bias modulation 116. As is demonstrated by this graph, the enhanced amplification unit 10 with auxiliary driver bias modulation has a higher level of efficiency in back-off. The enhanced amplification unit 10 with auxiliary driver bias modulation 116 illustrates an increase in system efficiency, and allows for efficiency to be increased where signal density is the highest.

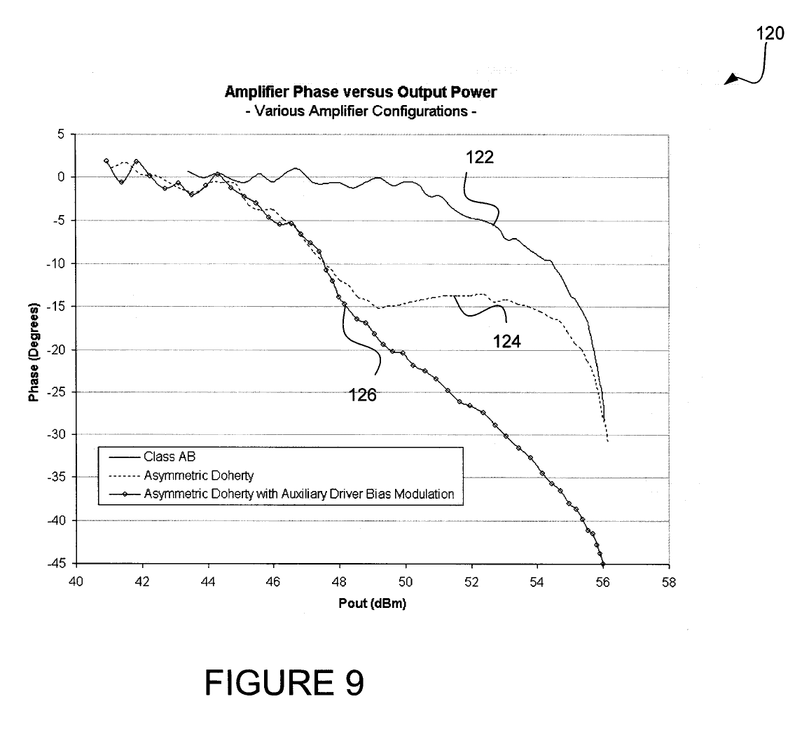

FIG. 9 is a chart 120 showing the amplifier phase versus the output power of a balanced AB amplifier 122, a Doherty with similar amplification devices 124, and an enhanced amplification unit with auxiliary driver bias modulation 126. As shown by this graph, the enhanced amplification unit with auxiliary driver bias modulation 126 has the most linear change of all of the approaches discussed and suggests a simplified amplitude modulated—phase modulated (AM-PM) characteristic.

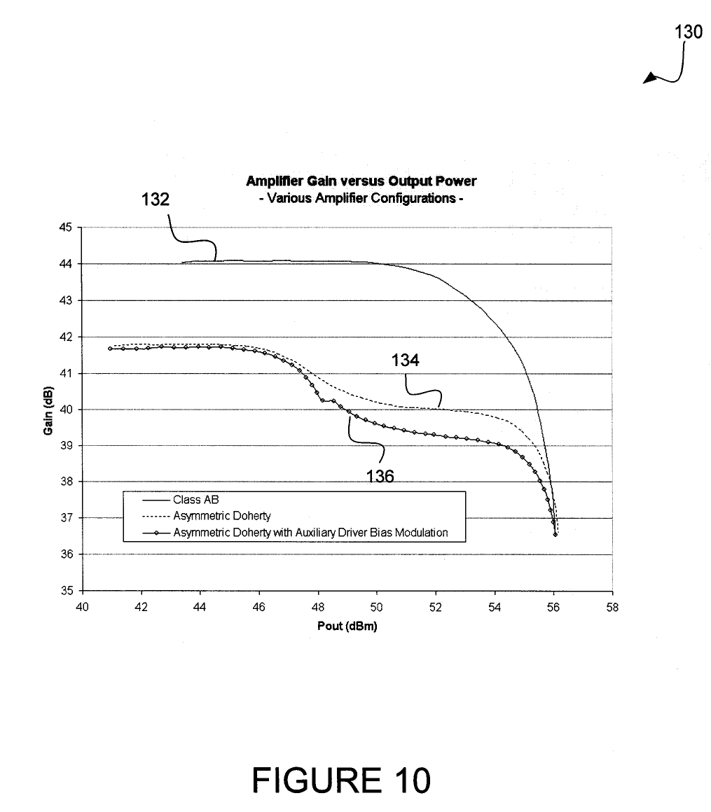

FIG. 10 is a chart 130 showing the amplifier gain versus the output power of a balanced AB amplifier 132, a Doherty with similar amplification devices 134, and an enhanced amplification unit with auxiliary driver bias modulation 136. As shown by this graph, the enhanced amplification unit with auxiliary driver bias modulation retains the profile of the Doherty with similar amplification devices 134 even with the addition of the bias modulation.

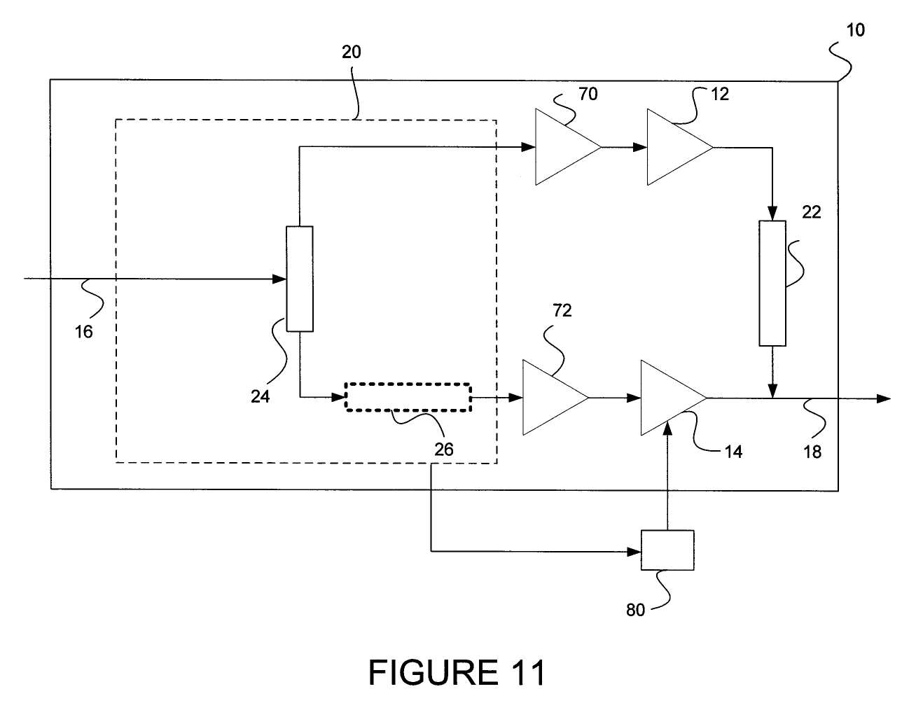

Another embodiment of an enhanced amplification unit 10 is shown by FIG. 11. This embodiment of enhanced amplification unit 10 also has a main amplifier 12 and auxiliary amplifier 14 connected in parallel, a main amplifier impedance transformer 22 connected to main amplifier 12 and auxiliary amplifier 14, and an output signal line 18 connected to auxiliary amplifier 14 and main amplifier impedance transformer 22. Main driver 70 has been placed in series in between the main amplifier 12 and signal splitter 24. In addition, auxiliary driver 72 has been placed in series in between auxiliary amplifier 14 and auxiliary path phase offset 26. In this embodiment, auxiliary amplifier bias control module 80 has been connected to auxiliary amplifier 14 and signal preparation unit 20. In the embodiment shown in FIG. 11, the amplifier designs of main amplifier 12 and auxiliary amplifier 14 may be dissimilar or consistent, with main amplifier 12 having, in some embodiments, approximately half the peak power rating of auxiliary amplifier 14. In the example shown in FIG. 11, signal splitter 24 may be implemented as a radio frequency (RF) power splitter or a digital power splitter.

In this embodiment, a signal is introduced through an input signal line 16, and transmitted into signal splitter 24. It is understood that if an RF power splitter is used, the signal for the main path and auxiliary path may be developed from the single input, and that if a digital power splitter is used, a power split may be preformed within the digital input circuitry of the digital power split device in any way known to one skilled in the art. It is further understood that signal splitter 24 splits the signal from signal line 16 into two input signals, and transmits these signals into main driver 70 which transmits a modified signal into main amplifier 12 and auxiliary path phase offset 26. The signal from auxiliary path phase offset 26 is transmitted into auxiliary driver 72 which transmits a modified signal into auxiliary amplifier 14. The output signal from main amplifier 12 is then passed from main amplifier 12 through a main amplifier impedance transformer 22 and becomes a modified output from main amplifier 12. The modified output of main amplifier 12 to main amplifier impedance transformer 22 combines with the output of the signal from auxiliary amplifier 14, becomes the output signal, and exits enhanced amplification unit 10 through output signal line 18.

FIG. 11 also illustrates the use of auxiliary amplifier bias control module 80. Auxiliary amplifier bias control module 80 adjusts the bias voltage applied by auxiliary amplifier 14. Therefore, auxiliary amplifier bias control module 80 adjusts the threshold and rate at which the gate bias is applied to the auxiliary amplifier while taking into consideration the input power. The gate bias modulation of the auxiliary amplifier 14 provides gain relief whereby, in some embodiments, the main amplifier does not saturate prematurely as well as reducing the complexity of the AM-AM transfer function. Moreover, the gate bias modulation allows for the simplification of the transfer function creating an extended range of linear gain as power increases. This results in a significantly more stable gain profile. Auxiliary amplifier bias control module 80 and auxiliary driver bias control module 74 may be similar or dissimilar devices biased at similar or dissimilar points.

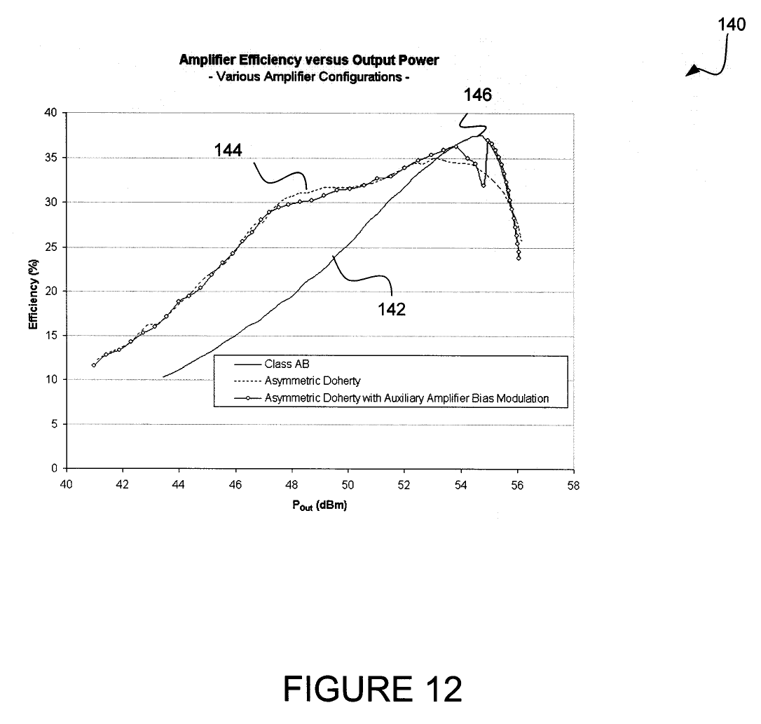

FIG. 12 is a graph 140 showing the amplifier efficiency versus the output power of a balanced AB amplifier 142, a Doherty with similar amplification devices 144, and an enhanced amplification unit 10 with auxiliary amplifier bias modulation 146. As is demonstrated by this graph, the enhanced amplification unit 10 with auxiliary amplifier bias modulation 146 retains the profile of the Doherty with similar amplification devices 144 even with the addition of the bias modulation.

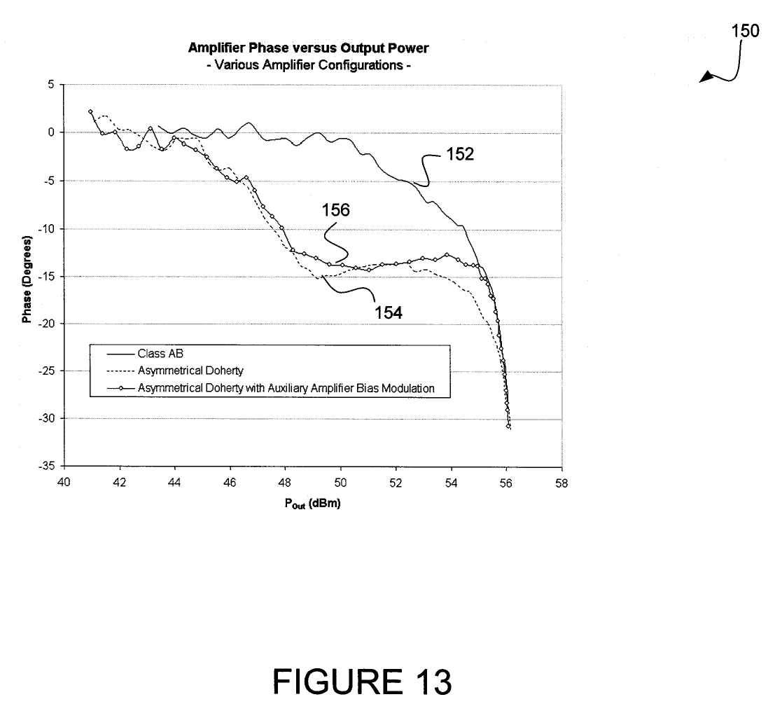

FIG. 13 is a chart 150 showing the amplifier phase versus the output power of a balanced AB amplifier 152, a Doherty with similar amplification devices 154, and an enhanced amplification unit with auxiliary amplifier bias modulation 156. As shown by this graph, the enhanced amplification unit with auxiliary amplifier bias modulation 156 retains the profile of the Doherty with similar amplification devices 154 even with the addition of the bias modulation.

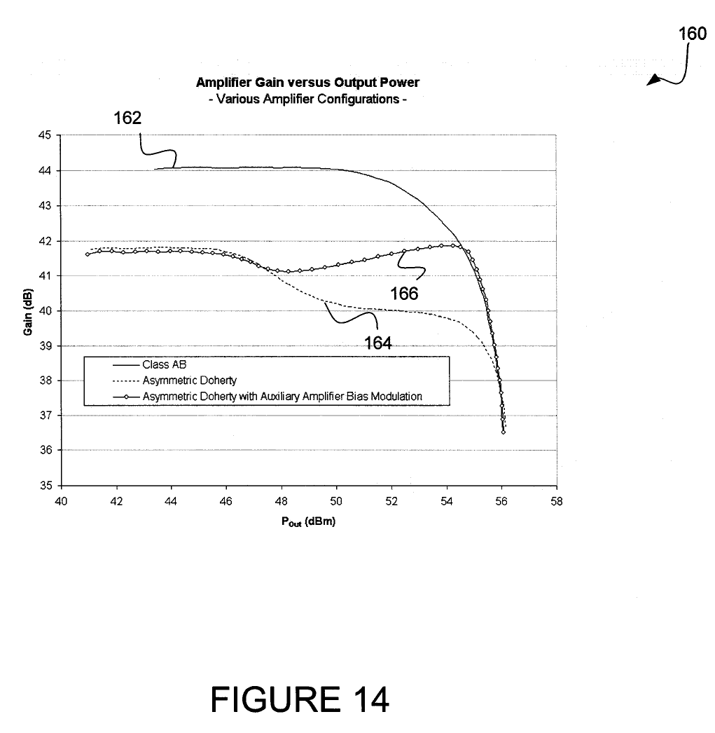

FIG. 14 is a chart 160 showing the amplifier gain versus the output power of a balanced AB amplifier 162, a Doherty with similar amplification devices 164, and an enhanced amplification unit with auxiliary amplifier bias modulation 166. As shown by this graph, the enhanced amplification unit with auxiliary amplifier bias modulation 166 provides significant gain relief as compared to a Doherty with similar amplification devices 164 and suggests a simplified amplitude modulated—amplitude modulated (AM-AM) characteristic.

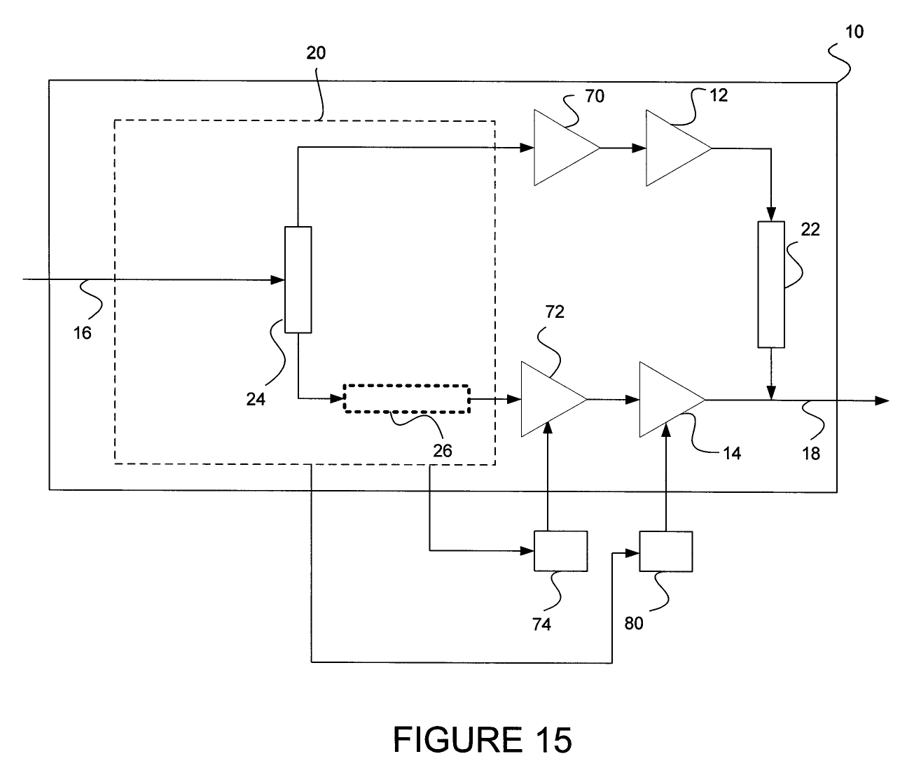

Another embodiment of an enhanced amplification unit 10 is shown by FIG. 15. This embodiment of enhanced amplification unit 10 also has a main amplifier 12 and auxiliary amplifier 14 connected in parallel, a main amplifier impedance transformer 22 connected to main amplifier 12 and auxiliary amplifier 14, and an output signal line 18 connected to auxiliary amplifier 14 and main amplifier impedance transformer 22. In this embodiment, a main driver 70 has been placed in series in between the main amplifier 12 and signal splitter 24. In addition, auxiliary driver 72 has been placed in series in between auxiliary amplifier 14 and auxiliary path phase offset 26. In this embodiment, both auxiliary amplifier bias control module 80 and auxiliary driver bias control module 74 have been connected as discussed above. In this embodiment, the amplifier designs of main amplifier 12 and auxiliary amplifier 14 may be dissimilar or consistent, with main amplifier 12 having, in some embodiments, approximately half the peak power rating of auxiliary amplifier 14. In the example shown in FIG. 15, signal splitter 24 may be implemented as a radio frequency (RF) power splitter or a digital power splitter. Auxiliary amplifier 14, in some embodiments, may be fundamentally biased in Class C. In one embodiment, the main amplifier 12 may have approximately 100 W peak power capacity and the auxiliary amplifier 14 may have approximately 200 W peak power capacity.

In this embodiment, a signal is introduced through an input signal line 16, and transmitted into signal into signal splitter 24. It is understood that if an RF power splitter is used, the signal for the main path and auxiliary path may be developed from the single input, and that if a digital power splitter is used, a power split may be performed within the digital input circuitry of the digital power split device in any way known to one skilled in the art. It is further understood that signal splitter 24 splits the signal from signal line 16 into two input signals, and transmits these signals into main driver 70 which transmits a modified signal into main amplifier 12 and auxiliary path phase offset 26. The signal from auxiliary path phase offset 26 is transmitted into auxiliary driver 72 which transmits a modified signal into auxiliary amplifier 14. The output signal from main amplifier 12 is then passed from main amplifier 12 through a main amplifier impedance transformer 22 and becomes a modified output from main amplifier 12. The modified output of main amplifier 12 to main amplifier impedance transformer 22 combines with the output of the signal from auxiliary amplifier 14 becomes the output signal, and exits enhanced amplification unit 10 through output signal line 18.

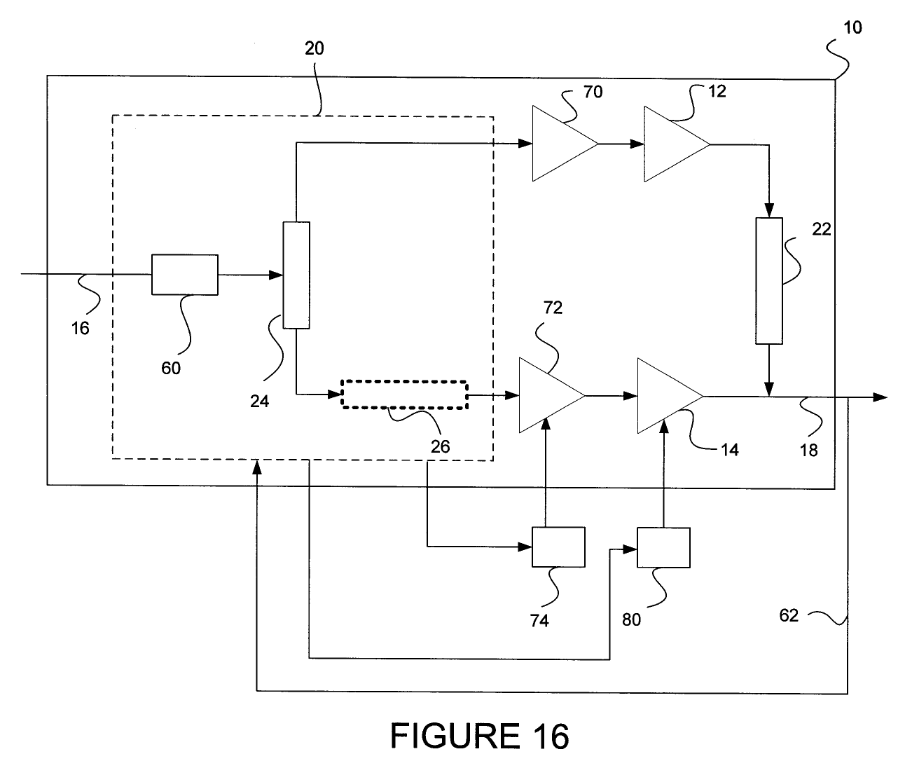

FIG. 16 also illustrates the use of auxiliary driver bias control module 74 and auxiliary amplifier bias control module 80 and is similar to the embodiment illustrated by FIG. 15, except with the addition of feedback signal line 62 and pre-distortion linearizer 60. Pre-distortion linearizer 60 is connected in series to input signal line 16 and signal splitter 24. Feedback signal line 62 is a connection from the output signal line 18 to the signal preparation unit 20, which allows pre-distortion linearizer 60 to monitor the signal in output signal line 18. In some embodiments, pre-distortion linearizer 60 may also be designed to implement some form of pre-distortion to account for any non-linearity introduced by signal shaping in enhanced amplification unit 10 output.

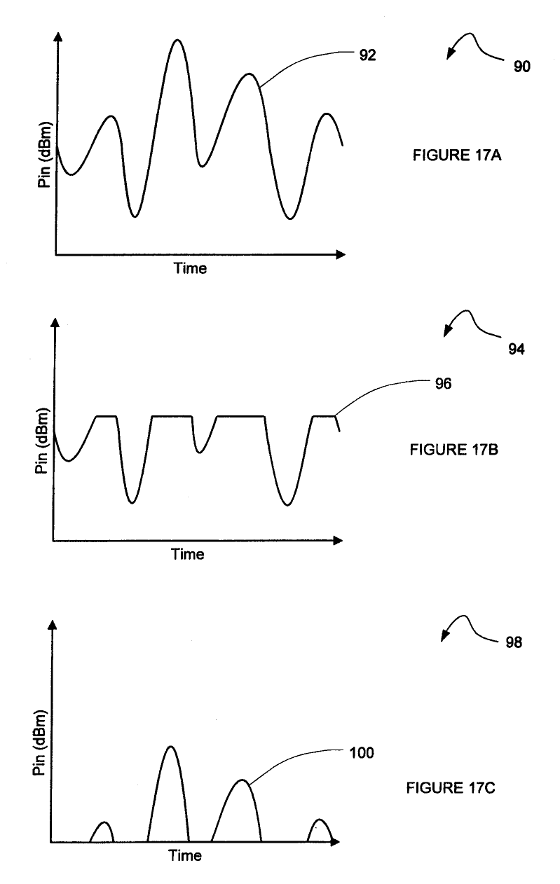

Signal shaping may result in two RF input signals developed digitally for amplification in enhanced amplification unit 10. Signal splitter 24, in some embodiments, splits and shapes a given signal into two signals. An example wave form demonstrating shaping is shown in FIGS. 17A, 17B, and 17C, which are plots of input power (Pin) as a function of time. FIG. 17A is a plot 90 of an input signal 92. FIG. 17B is a plot 94 of main portion 96 of input signal 92. FIG. 17C is a plot 98 of auxiliary portion 100 of input signal 92. Main portion 96 may comprise the portion of input signal 92 that may be amplified by main amplifier 12 without reaching the saturation point. Auxiliary portion 100 comprises the portion of input signal 92 remaining after main portion 96 has been separated, and auxiliary portion 100 may comprise the portion of input signal 92 that may be amplified by auxiliary amplifier 14. Signal preparation unit 20 may be capable of a customized transfer of power to each amplifier. In some embodiments, pre-distortion linearizer 60 may also be designed to implement some form of pre-distortion to account for any non-linearity introduced by signal shaping in enhanced amplification unit 10.

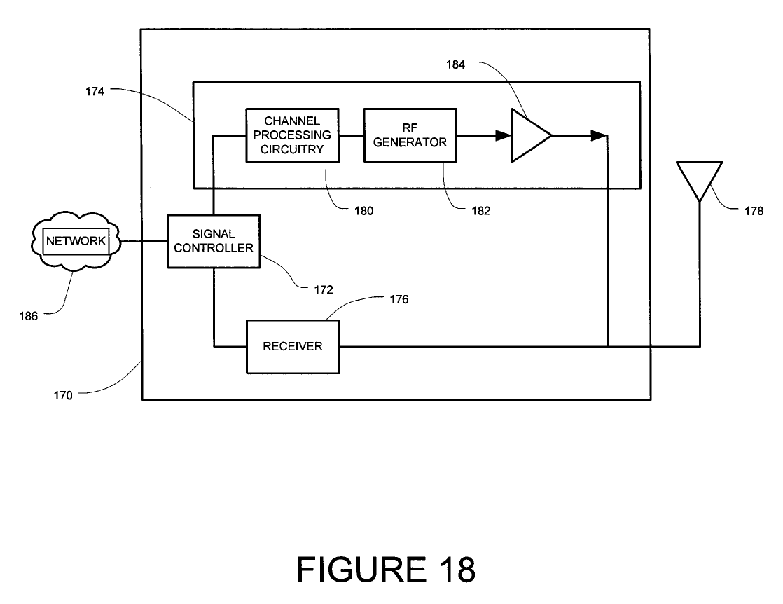

As shown in FIG. 18, disclosed enhanced amplification unit 10 design may be incorporated as enhanced amplifier 184 into a base station 170. Base station 170 is a medium to high-power multi-channel, two-way radio in a fixed location. Typically it may be used by low-power, single-channel, two-way radios or wireless devices such as mobile phones, portable phones and wireless routers. Base station 170 may comprise a signal controller 172 that is coupled to a transmitter 174 and a receiver 176. Transmitter 174 and receiver 176 (or combined transceiver) is further coupled to an antenna 178. In base station 170, digital signals are processed in signal controller 172. The digital signals may be signals for a wireless communication system, such as signals that convey voice or data intended for a mobile terminal (not shown). Base station 170 may employ any suitable wireless technologies or standards such as 2G, 2.5G, 3G, GSM, IMT-2000, UMTS, iDEN, GPRS, EV-DO, EDGE, DECT, PDC, TDMA, FDMA, CDMA, W-CDMA, TD-CDMA, TD-SCDMA, GMSK, OFDM, etc. Signal controller 172 then transmits the digital signals to transmitter 174, which includes a channel processing circuitry 180. Channel processing circuitry 180 encodes each digital signal, and a radio frequency (RF) generator 182 modulates the encoded signals onto an RF signal. The RF signal is then amplified in an enhanced amplification unit 10. The resulting output signal is transmitted over antenna 178 to the mobile terminal. Antenna 178 also receives signals sent to base station 170 from the mobile terminal. Antenna 178 transmits the signals to receiver 176 that demodulates them into digital signals and transmits them to signal controller 172 where they may be relayed to an external network 186. Base station 170 may also comprise auxiliary equipment such as cooling fans or air exchangers for the removal of heat from base station 170.

In an embodiment, the enhanced amplification unit 10 of the present disclosure may be incorporated into base station 170 in lieu of parts, if not all, of blocks 182 and 184, which may decrease the capital costs and power usage of base station 170. The power amplifier efficiency measures the usable output signal power relative to the total power input. The power not used to create an output signal is typically dissipated as heat. In large systems such as base station 170, the heat generated in enhanced amplification unit 10 may require cooling fans and other associated cooling equipment that may increase the cost of base station 170, require additional power, increase the overall size of the base station housing, and require frequent maintenance. Increasing the efficiency of enhanced amplification unit 10 in base station 170 may eliminate the need for some or all of the cooling equipment. Further, the supply power to enhanced amplification unit 10 may be reduced since it may more efficiently be converted to a usable signal. The physical size of base station 170 and the maintenance requirements may also be reduced due to the reduction of cooling equipment. This may enable base station 170 equipment to be moved to the top of a base station tower, allowing for shorter transmitter cable runs and reduced costs. In an embodiment, base station 170 has an operating frequency ranging from 800 MHz to 3.5 GHz.

While preferred embodiments of the invention have been shown and described, modifications thereof can be made by one skilled in the art without departing from the spirit and teachings of the invention. The embodiments described herein are exemplary only, and are not intended to be limiting. Many variations and modifications of the invention disclosed herein are possible and are within the scope of the invention. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). Use of the term “optionally” with respect to any element of a claim is intended to mean that the subject element is required, or alternatively, is not required. Both alternatives are intended to be within the scope of the claim. Use of broader terms such as comprises, includes, having, etc. should be understood to provide support for narrower terms such as consisting of, consisting essentially of, comprised substantially of, etc.

Accordingly, the scope of protection is not limited by the description set out above but is only limited by the claims which follow, that scope including all equivalents of the subject matter of the claims. Each and every claim is incorporated into the specification as an embodiment of the present invention. Thus, the claims are a further description and are an addition to the preferred embodiments of the present invention. The discussion of a reference in the Description of Related Art is not an admission that it is prior art to the present invention, especially any reference that may have a publication date after the priority date of this application. The disclosures of all patents, patent applications, and publications cited herein are hereby incorporated by reference, to the extent that they provide exemplary, procedural or other details supplementary to those set forth herein.

1. An amplification unit comprising:
a signal splitter, wherein the signal splitter is operable to split an input signal into a first signal and a second signal such that the two resulting signal portions are in quadrature;
a main driver operable to create a third signal from the first signal;
a main amplifier; wherein the main amplifier is operable to amplify the third signal;
an auxiliary driver operable to create a fourth signal from the second signal;
an auxiliary amplifier, wherein the auxiliary amplifier is operable to amplify the fourth signal;
a bias control module, wherein the bias control module is operable to control at least part of the amplified fourth signal created by the auxiliary amplifier; and
a signal combiner, wherein the signal combiner is operable to combine the amplified third signal and the amplified fourth signal and realign the phase of the amplified third signal and amplified fourth signal.

2. The amplification unit of claim 1 wherein the main and auxiliary amplifiers have either substantially different or substantially similar power ratings and are formed utilizing semiconductor device technologies selected from the group comprising: a laterally diffused metal oxide semiconductor (LDMOS), a complementary metal oxide semiconductor (CMOS), a metal oxide semiconductor field effect transistor (MOSFET), a metal semiconductor field effect transistor (MESFET), a heterojunction bipolar transistor (HBT), a high electron mobility transistor (HEMT), heterojunction field effect transistor (HFET), a bipolar junction transistor (BJT), or combination thereof.

3. The amplification unit of claim 2 wherein signal splitter is a digital or analog signal splitter.

4. The amplification unit of claim 1 wherein the main and auxiliary amplifiers are biased as a dissimilar class selected from the group: Class A, Class AB, Class B or Class C.

5. The amplification unit of claim 1 wherein relative phase of the first signal and second signals is shifted away from quadrature so as to ensure the amplified signals combine in phase to account for variations introduced by combining one or more of mixed semiconductor device technologies, materials, power ratings or bias conditions.

6. The amplification unit of claim 2, wherein the main and auxiliary amplifiers are comprised of semiconductor materials selected from the group comprising: silicon (Si), indium phosphide (InP), gallium arsenide (GaAs), or gallium nitride (GaN), or combination thereof.

7. The amplification unit of claim 6 wherein input phase manipulation is achieved using digital baseband or RF delay techniques.

8. The amplification unit of claim 7 wherein the amplification unit is integrated with a mobile phone base station, satellite or satellite communication device, radio unit, or other electrical device.

9. The amplification unit of claim 7 further comprising linearization with memory correction wherein the input signal is pre-distorted to account for device non-linearities and memory when operating within the desired range.

10. The amplification unit of claim 9 further comprising a pre-distortion linearizer coupled to the input signal line and providing an output signal to the signal splitter.

11. The amplification unit of claim 10 further comprising a feedback signal line, which includes a signal representative of the state of the output signal, to the pre-distortion linearizer, the signal splitter or both the pre-distortion linearizer and signal splitter.

12. The method of claim 11, wherein the bias control module is connected to the auxiliary driver or the auxiliary amplifier.

13. The method of claim 12, further comprising a second bias control, wherein the first bias control is connected to the auxiliary driver and the second bias control is connected to the auxiliary amplifier.

14. The amplification unit of claim 13 wherein the bias control module and the second bias control module are substantially similar devices.

15. The amplification unit of claim 14, wherein the bias control and the second bias control alter the operating parameters of auxiliary driver, auxiliary amplifier, or both the auxiliary driver and auxiliary amplifier based upon information from the feedback signal line.

16. A method of amplifying an input signal comprising:
separating the input signal into a first portion and a second portion;
amplifying the first portion using a main driver and a main amplifier;
amplifying the second portion using an auxiliary driver and an auxiliary amplifier;
controlling the amplification of the second portion using a bias control module; and
combining the amplified first portion and the amplified second portion.

17. The method of claim 16, further comprising phase shifting the input signal before amplifying the first portion using the main amplifier and the second portion using the auxiliary amplifier.

18. The method of claim 17, further comprising realigning the phase of an output signal from one of the amplifiers before combining the amplified first portion and the amplified second portion.

19. The method of claim 18, wherein the bias control module is connected to the auxiliary driver or the auxiliary amplifier.

20. The method of claim 18, further comprising a second bias control, wherein the first bias control module is connected to the auxiliary driver and the second bias control module is connected to the auxiliary amplifier.
